(19) United States
(12) Patent Application Publication
(10) Pub. No.: US 2007/0014919 A1
(43) Pub. Date: Jan. 18, 2007

(54) Atomic layer deposition of noble metal oxides

(76) Inventors: Jani Hamalainen, Espoo (FI); Mikko Ritala, Espoo (FI); Markku Leskela, Espoo (FI)

Correspondence Address: KNOBBE MARTENS OLSON & BEAR LLP, 2040 MAIN STREET, FOURTEENTH FLOOR, IRVINE, CA, 92614, US

(21) Appl. No.: 11/182,734

(22) Filed: Jul. 15, 2005

(51) Int. Cl. C23C 16/00

(52) U.S. Cl. 427/248.1

(57) ABSTRACT

Electrically conductive noble metal oxide films can be deposited by atomic layer deposition (ALD)-type processes. In preferred embodiments, Re, Ru, Os and Ir oxides are deposited by alternately and sequentially contacting a substrate with vapor phase pulses of a noble metal precursor and an oxygen source. The noble metal precursor is preferably a betadiketonate compound and the oxygen source is preferably ozone or oxygen plasma. The deposition temperature may be less than about 200° C.

### BACKGROUND OF THE INVENTION

1. Field of the Invention

The present invention relates generally to processes for producing noble metal oxide thin films on a substrate by atomic layer deposition.

2. Description of the Related Art

Noble metal oxide thin films have high work function, good oxidation resistance and good barrier properties. As a result, they have a variety of potential applications in microelectronics and in other fields. For example, in the semiconductor industry noble metal oxides can be used as a material for electrodes in DRAMs and FRAMs, as gate electrodes in integrated circuits and as barrier and seed layers for interconnect metallization.

ALD is a self-limiting process, whereby alternated pulses of reaction precursors saturate a substrate surface and leave no more than one monolayer of material per pulse. The deposition conditions and precursors are selected to ensure self-saturating reactions, such that an adsorbed layer in one pulse leaves a surface termination that is non-reactive with the gas phase reactants of the same pulse. A subsequent pulse of different reactants reacts with the previous termination to enable continued deposition. Thus, each cycle of alternated pulses leaves no more than about one molecular layer of the desired material. The principles of ALD type processes have been presented by T. Suntola, e.g. in the Handbook of Crystal Growth 3, Thin Films and Epitaxy, Part B: Growth Mechanisms and Dynamics, Chapter 14, Atomic Layer Epitaxy, pp. 601-663, Elsevier Science B.V. 1994, the disclosure of which is incorporated herein by reference. Variations of ALD have been proposed that allow for modulation of the growth rate. However, to provide for high conformality and thickness uniformity, these reactions are still more or less self-saturating.

In a typical ALD process for depositing metal oxides, one deposition cycle comprises exposing the substrate to a metal precursor, removing unreacted first reactant and reaction byproducts from the reaction chamber, exposing the substrate to an oxygen precursor followed by a second removal step.

### SUMMARY OF THE INVENTION

Thin films of conductive noble metal oxides, particularly Ru, Re, Os and Ir oxides, can be deposited using atomic layer deposition. A substrate is alternately contacted with a noble metal precursor and a second reactant comprising an oxygen source. In preferred embodiments the noble metal precursor is a betadiketonate compound and the oxygen source is ozone or oxygen plasma. The atomic layer deposition reaction is preferably carried out at a temperature of about 300° C. or less, more preferably at a temperature of about 200° C. or less.

In some embodiment, an atomic layer deposition process for forming a noble metal oxide thin film comprises alternately and sequentially contacting a substrate with a noble metal precursor and ozone or oxygen plasma. The noble metal precursor preferably comprises a noble metal selected from the group consisting of Ru, Re, Os and Ir. The precursor preferably comprises a noble metal may be bound to oxygen, nitrogen or carbon and more preferably is a betadiketonate compound such as X(acac)₃, where X is Ru, Re, Os or Ir and acac is acetylacetone.

The process is preferably carried out at a deposition temperature of less than about 300° C., more preferably less than about 200° C.

In other embodiments, an electrically, conductive noble metal oxide is produced on a substrate by exposing the substrate in a reaction chamber to a vapor phase noble metal precursor such that no more than one monolayer of the precursor is adsorbed on the substrate. The excess noble metal precursor is removed and the substrate is subsequently exposed to ozone or oxygen plasma. Excess ozone is removed from the chamber and the cycle is repeated to form a film of the desired thickness. The noble metal precursor preferably comprises a noble metal selected from the group consisting of Ru, Re, Os and Ir and in some embodiments is preferably a betadiketonate compound. The process may be carried out at a temperature of less than about 300° C., more preferably less than about 200° C.

In still other embodiments, an atomic layer deposition process is provided for forming a conductive noble metal oxide thin film on a substrate from vapor phase pulse of a noble metal source and an oxygen source, wherein the noble metal precursor comprises a noble metal selected from the group consisting of Ru, Re, Os and Ir and the process is carried out at a temperature of less than about 300° C., more preferably less than about 200° C.

In further embodiments, an ALD type process is provided for depositing noble metal oxides comprising Re, Os and/or Ir. A substrate is alternately and sequentially contacted with a vapor phase betadiketonate noble metal source chemical and an oxygen source, such as ozone or oxygen plasma. The process may be carried out at a temperature of less than about 300° C., more preferably less than about 200° C.

In some embodiments a capacitor electrode is formed by depositing an electrically conductive noble metal oxide by ALD.

In other embodiments a gate electrode is formed by depositing a gate dielectric layer and depositing a noble metal oxide over the gate dielectric layer by an atomic layer deposition process.

In still other embodiments, a barrier layer and/or seed layer in a metal interconnect structure is formed by depositing a noble metal oxide layer by ALD.

### BRIEF DESCRIPTION OF THE DRAWINGS

FIG. 1 is a schematic illustration of a basic capacitor structure.

FIG. 2 is a schematic side view of the structure of a DRAM capacitor after the formation of a conductor peg and the deposition of capacitor thin films.

FIG. 3 is a schematic side view of the structure of a DRAM capacitor after the formation of a capacitor hollow and the deposition of capacitor thin films.

FIG. 4 is a schematic side view of the structure of a DRAM trench capacitor.

FIG. 5 is a schematic illustration of a semiconductor substrate comprising a high-k dielectric layer after deposition of a conductive noble metal oxide layer by ALD and prior to patterning to form a gate electrode.

FIG. 6 is a schematic illustration of a dual damascene structure comprising a noble metal barrier layer.

FIG. 7 is a schematic illustration of a dual damascene structure comprising a noble metal seed layer.

FIG. 8 illustrates the growth rate and sensitivity of IrO₂ film as a function of ozone pulse length. The solid squares indicate IrO₂ growth rate on soda lime glass substrates. The deposition temperature was about 175° C.

FIG. 9 illustrates the growth rate and resistivity of ALD deposited IrO₂ films as a function of the ozone dose. The solid squares indicate IrO₂ growth rate on soda lime glass substrates. The deposition temperature was about 175° C.

FIG. 10 shows the XRD pattern of IrO₂ thin film deposited by ALD on a silicon substrate at about 175° C.

### DETAILED DESCRIPTION

Noble metal oxide thin films can be deposited on a substrate by atomic layer deposition (ALD) type processes. ALD type processes are based on controlled, self-limiting surface reactions of precursor chemicals. Gas phase reactions are avoided by feeding the precursors alternately and sequentially into the reaction chamber. Vapor phase reactants are separated from each other in the reaction chamber, for example, by removing excess reactants and/or reactant by-products from the reaction chamber between reactant pulses.

Briefly, a substrate is loaded into a reaction chamber and is heated to a suitable deposition temperature, generally at lowered pressure. Deposition temperatures are maintained below the precursor thermal decomposition temperature but at a high enough level to avoid condensation of reactants and to provide the activation energy for the desired surface reactions. Of course, the appropriate temperature window for any given ALD reaction will depend upon the surface termination and reactant species involved. Here, the temperature is preferably at or below about 300° C., more preferably at or below about 200° C.

A first reactant is conducted into the chamber in the form of vapor phase pulse and contacted with the surface of the substrate. Conditions are preferably selected such that no more than about one monolayer of the precursor is adsorbed on the substrate surface in a self-limiting manner. Excess first reactant and reaction byproducts, if any, are purged from the reaction chamber, often with a pulse of inert gas such as nitrogen or argon.

Purging the reaction chamber means that vapor phase precursors and/or vapor phase byproducts are removed from the reaction chamber such as by evacuating the chamber with a vacuum pump and/or by replacing the gas inside the reactor with an inert gas such as argon or nitrogen. Typical purging times are from about 0.05 to 20 seconds, more preferably between about 1 and 10, and still more preferably between about 1 and 2 seconds. However, other purge times can be utilized if necessary, such as when depositing noble metal oxides in situations where highly conformal step coverage over extremely high aspect ratio structures or other structures with complex surface morphology is needed, such as in Micro-Electro-Mechanical Systems (MEMS). The appropriate pulsing times can be readily determined by the skilled artisan based on the particular circumstances.

A second gaseous reactant is pulsed into the chamber where it reacts with the first reactant bound to the surface. Excess second reactant and gaseous by-products of the surface reaction are purged out of the reaction chamber, preferably with the aid of an inert gas. The steps of pulsing and purging are repeated until a thin film of the desired thickness has been formed on the substrate, with each cycle leaving no more than a molecular monolayer.

As mentioned above, each pulse or phase of each cycle is preferably self-limiting. An excess of reactant precursors is supplied in each phase to saturate the susceptible structure surfaces. Surface saturation ensures reactant occupation of all available reactive sites (subject, for example, to physical size or “steric hindrance” restraints) and thus ensures excellent step coverage.

According to a preferred embodiment, a noble metal oxide thin film is formed on a substrate by an ALD type process comprising multiple pulsing cycles, each cycle comprising:
pulsing a vaporized noble metal precursor into the reaction chamber to form at most a molecular monolayer of the metal precursor on the substrate,
purging the reaction chamber to remove excess noble metal precursor and reaction by products, if any,
providing a pulse of a second reactant comprising an oxygen source, preferably ozone, onto the substrate,
purging the reaction chamber to remove excess second reactant and any gaseous by-products formed in the reaction between the noble metal precursor layer on the first surface of the substrate and the second reactant, and
repeating the pulsing and purging steps until a noble metal oxide thin film of the desired thickness has been formed.

The noble metal thin oxide film typically comprises multiple monolayers of a single noble metal oxide. However, in other embodiments, the final metal structure may comprise two or more different noble metal oxides. For example, the growth can be started with the deposition of a first noble metal oxide and ended with the deposition of a second noble metal oxide. In other embodiments, alternating layers of noble metal oxides can be deposited.

The substrate can comprise various types of materials. When manufacturing integrated circuits, the substrate typically comprises a number of thin films with varying chemical and physical properties. For example and without limitation, the substrate may comprise a dielectric layer, such as aluminum oxide, hafnium oxide, hafnium silicate, tantalum oxide, zirconium oxide, a metal, such as Ta, Ti, or W, a metal nitride, such as TaN, TiN, NbN, MoN or WN, silicon, silicon germanium, germanium or polysilicon. Further, the substrate surface may have been patterned and may comprise structures such as nodes, vias, trenches or micromechanical systems (MEMS).

The noble metal oxide is preferably selected from the group consisting of Ru, Re, Os and Ir oxides and is preferably electrically conductive.

Suitable noble metal precursors may be selected by the skilled artisan. In general, metal compounds where the metal is bound or coordinated to oxygen, nitrogen, carbon or a combination thereof are preferred. In some embodiments the noble metal precursors are organic compounds. More preferably betadiketonate compounds are used. In some embodiments, X(acac)₃ or X(thd)_{y} compounds are used, where X is a noble metal, y is generally, but not necessarily between 2 and 3 and thd is 2,2,6,6-tetramethyl-3,5-heptanedionato.

When depositing ruthenium oxide thin films, preferred metal precursors can be selected from the group consisting of ruthenium betadiketonate compounds, ruthenium cyclopentadienyl compounds, ruthenium carbonyl compounds and combinations thereof. The ruthenium precursor may also comprise one or more halide ligands. In preferred embodiments, the precursor is Ru(acac)₃ or Ru(thd)₃.

In some embodiments electrically conductive Ru oxide, preferably RuO₂, is deposited from alternating and sequential pulses of a Ru precursor and an oxygen source, preferably ozone. The Ru precursor preferably comprises a betadiketonate and more preferably is Ru(acac)₃. The temperature is preferably less than about 300° C., more preferably less than about 200° C.

When depositing rhenium oxide thin films, preferred metal precursors may be selected from the group consisting of rhenium betadiketonate compounds, rhenium cyclopentadienyl compounds, rhenium carbonyl compounds and combinations thereof. The rhenium precursor may also comprise one or more halide ligands. In preferred embodiments, the precursor is Re(acac)₃ or Re(thd)₃.

In some embodiments electrically conductive Re oxide, preferably ReO₂, Re₂O₅, Re₂O₇ or ReO₃, is deposited from alternating and sequential pulses of a Re precursor and an oxygen source, preferably ozone. The Re precursor is preferably comprises a betadiketonate compound and more preferably is Re(acac)₃. The temperature is preferably less than about 300° C., more preferably less than about 200° C.

When depositing osmium oxide thin films, preferred metal precursors may be selected from the group consisting of osmium betadiketonate compounds, osmium cyclopentadienyl compounds, osmium carbonyl compounds and combinations thereof. The osmium precursor may also comprise one or more halide ligands. In preferred embodiments, the precursor is Os(acac)₃ or Os(thd)₃.

In some embodiments electrically conductive Os oxide, preferably OsO₂, is deposited from alternating and sequential pulses of an Os precursor and an oxygen source, preferably ozone. The Os precursor is preferably comprises a betadiketonate compound and more preferably is Os(acac)₃. The temperature is preferably less than about 300° C., more preferably less than about 200° C.

When depositing iridium oxide thin films, preferred metal precursors may be selected from the group consisting of iridium betadiketonate compounds, iridium cyclopentadienyl compounds, iridium carbonyl compounds and combinations thereof. The iridium precursor may also comprise one or more halide ligands. In preferred embodiments, the precursor is Ir(acac)₃ or Ir(thd)₃.

In some embodiments electrically conductive Ir oxide, preferably IrO₂, is deposited from alternating and sequential pulses of an Ir precursor and an oxygen source, preferably ozone. The Ir precursor is preferably comprises a betadiketonate compound and more preferably is Ir(acac)₃. The temperature is preferably less than about 300° C., more preferably less than about 200° C.

The noble metal precursor employed in the ALD type processes may be solid, liquid or gaseous material under standard conditions (room temperature and atmospheric pressure), provided that the metal precursor is in vapor phase before it is conducted into the reaction chamber and contacted with the substrate surface. “Pulsing” a vaporized precursor onto the substrate means that the precursor vapor is conducted into the chamber for a limited period of time. Typically, the pulsing time is from about 0.05 to 10 seconds. However, depending on the substrate type and its surface area, the pulsing time may be even higher than 10 seconds.

Preferably, for a 300 mm wafer in a single wafer ALD reactor, the noble metal precursor is pulsed for from 0.05 to 10 seconds, more preferably for from 0.1 to 5 seconds and most preferably for about 0.3 to 3.0 seconds. The oxygen-containing precursor is preferably pulsed for from about 0.05 to 10 seconds, more preferably for from 0.1 to 5 seconds, most preferably about for from 0.2 to 3.0 seconds. However, pulsing times can be on the order of minutes in some cases. The optimum pulsing time can be readily determined by the skilled artisan based on the particular circumstances.

The mass flow rate of the noble metal precursor can be determined by the skilled artisan. In one embodiment, for deposition on 300 mm wafers the flow rate of noble metal precursor is preferably between about 1 and 1000 sccm without limitation, more preferably between about 100 and 500 sccm. The mass flow rate of the noble metal precursor is usually lower than the mass flow rate of the oxygen source, which is usually between about 10 and 10000 sccm without limitation, more preferably between about 100-2000 sccm and most preferably between 100-1000 sccm.

The pressure in the reaction chamber is typically from about 0.01 and 20 mbar, more preferably from about 1 to about 10 mbar. However, in some cases the pressure will be higher or lower than this range, as can be readily determined by the skilled artisan.

The oxygen source may be an oxygen-containing gas pulse and can be a mixture of oxygen and inactive gas, such as nitrogen or argon. In some embodiments the oxygen source may be a molecular oxygen-containing gas pulse. The preferred oxygen content of the oxygen-source gas is from about 10 to 25%. Thus, one source of oxygen may be air. In preferred embodiments the oxygen source comprises an activated or excited oxygen species. In some embodiments the oxygen source comprises ozone. The oxygen source may be pure ozone or a mixture of ozone and another gas, for example an inactive gas such as nitrogen or argon. In other embodiments the oxygen source is oxygen plasma.

As mentioned above, the noble metal ALD process typically comprises alternating pulses of noble metal precursor and a reactant comprising an oxygen source. The oxygen source pulse may be provided, for example, by pulsing ozone or a mixture of ozone and another gas into the reaction chamber. In other embodiments, ozone is formed inside the reactor, for example by conducting oxygen containing gas through an arc. In other embodiments an oxygen containing plasma is formed in the reactor. In some embodiments the plasma may be formed in situ on top of the substrate or in close proximity to the substrate. In other embodiments the plasma is formed upstream of the reaction chamber in a remote plasma generator and plasma products are directed to the reaction chamber to contact the substrate. As will be appreciated by the skilled artisan, in the case of a remote plasma the pathway to the substrate can be optimized to maximize electrically neutral species and minimize ion survival before reaching the substrate.

The pressure in the reaction space is typically between about 0.01 and 20 mbar, more preferably between about 1 and 10 mbar.

Before starting the deposition of the film, the substrate is typically heated to a suitable growth temperature. Preferably, the growth temperature of the metal thin film is less than about 300° C., more preferably less than about 250° C. and even more preferably less than about 200° C. The preferred deposition temperature may vary depending on a number of factors such as, and without limitation, the reactant precursors, the pressure, flow rate, the arrangement of the reactor, and the composition of the substrate including the nature of the material to be deposited on. The specific growth temperature may be selected by the skilled artisan using routine experimentation.

The processing time depends on the thickness of the layer to be produced and the growth rate of the film. In ALD, the growth rate of a thin film is determined as thickness increase per one cycle. One cycle consists of the pulsing and purging steps of the precursors and the duration of one cycle is typically between about 0.2 and 30 seconds, more preferably between about 1 and 10 seconds, but it can be on order of minutes or more in some cases.

Examples of suitable reactors that may be used for the deposition of thin films according to the processes of the present invention include commercially available ALD equipment such as the F-120® reactor, Pulsar® reactor and EmerALD™ reactor, available from ASM America, Inc of Phoenix, Ariz. In addition to these ALD reactors, many other kinds of reactors capable of ALD growth of thin films, including CVD reactors equipped with appropriate equipment and means for pulsing the precursors, can be employed. Preferably, reactants are kept separate until reaching the reaction chamber, such that shared lines for the precursors are minimized. However, other arrangements are possible, such as the use of a pre-reaction chamber as described in U.S. application Ser. Nos. 10/929,348, filed Aug. 30, 2004 and 09/836,674, filed Apr. 16, 2001, the disclosures of which are incorporated herein by reference.

The growth processes can optionally be carried out in a reactor or reaction space connected to a cluster tool. In a cluster tool, because each reaction space is dedicated to one type of process, the temperature of the reaction space in each module can be kept constant, which improves the throughput compared to a reactor in which is the substrate is heated up to the process temperature before each run.

A stand-alone reactor can be equipped with a load-lock. In that case, it is not necessary to cool down the reaction space between each run.

While illustrated in the context of formation of capacitor electrodes, gate electrodes, barrier and seed layers, the skilled artisan will readily find application for the principles and advantages disclosed herein in other contexts.

Formation of Capacitor Electrodes

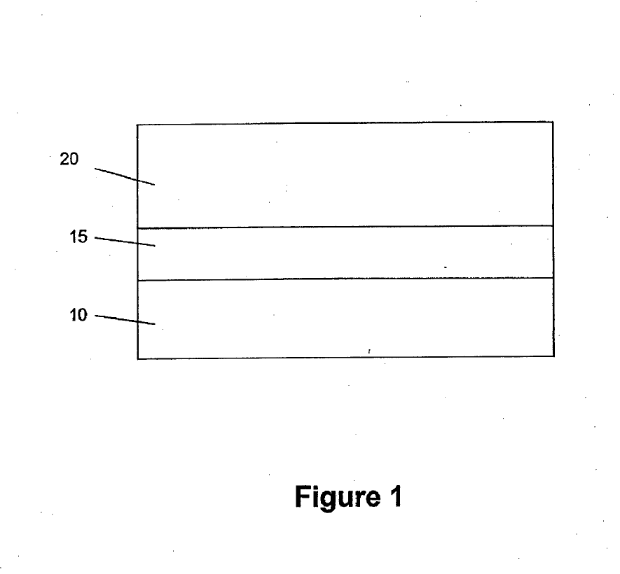

The ALD process may be used to deposit electrically conductive noble metal oxide thin films which form capacitor electrodes. A basic capacitor structure is illustrated in FIG. 1, in which a storage electrode 10 is separated from a reference electrode 20 by a high k layer 15. One or both of the storage electrode 10 and reference electrode 20 may be formed by an ALD deposited conductive noble metal oxide thin film. One of skill in the art will recognize that the ALD process for depositing noble metal oxide films can be used to form one or both electrodes in capacitors of any form, including, without limitation, a stud capacitor, a trench capacitor, and a container capacitor. Several particular embodiments are described below. The nature of the ALD process allows for conformal deposition on structures with complex morphology, such as three-dimensional folding structures and HSG silicon that are commonly used in forming capacitors, particularly for dense memory array structures, such as dynamic random access memories (DRAMs).

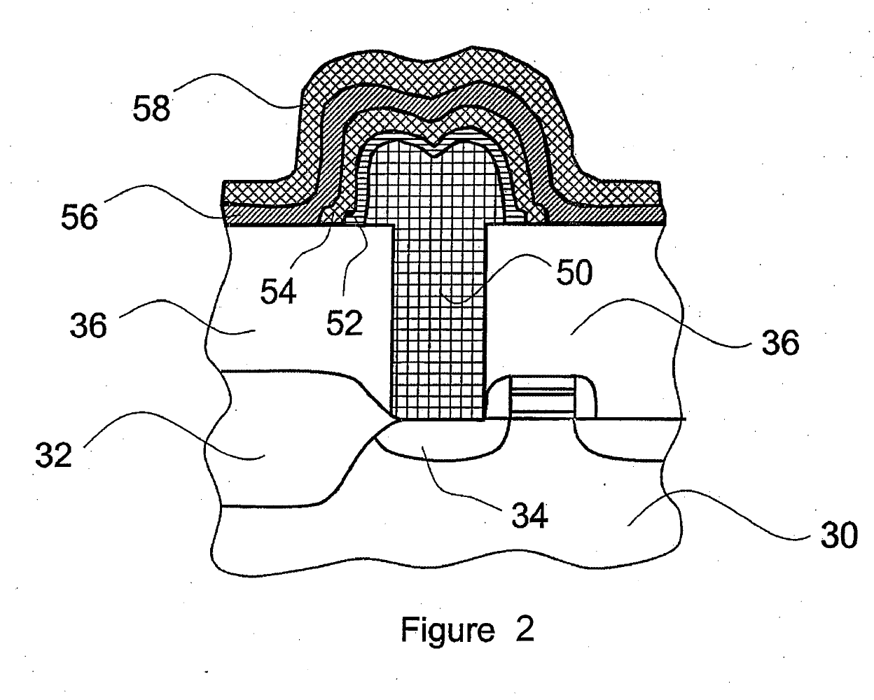

In one embodiment, a silicon substrate 30 is provided, with a doped region 34 that is an active part of a transistor, as illustrated in FIG. 2. Field oxide 32 separates the transistors from each other. An insulator layer 36, e,g., SiO₂, is grown on the substrate and a via is etched through the insulator and filled with a conductor material 50, e.g. polysilicon. The polysilicon layer is patterned and etched so that the via plug and a tooth-like extension over the plug remain on the structure. Although a noble metal oxide could be used in place of the polysilicon, the polysilicon tooth minimizes the amount of expensive metal that is needed for the lower electrode. The exposed surface of the polysilicon may be very rough after the etching step so that the surface area of polysilicon is as large as possible. A barrier layer 52, e.g., tantalum silicon nitride TaₓSi_{y}N_{z}, may be deposited over the substrate by, e.g., Atomic Layer Deposition (ALD). The barrier layer is patterned and etched so that there is barrier layer left only on and near the polysilicon surface. In some embodiments the barrier layer may be omitted, for example if a noble metal oxide with good barrier properties is utilized as the lower electrode.

A conductive noble metal oxide lower electrode 54 is grown by ALD on the substrate as described above and then the noble metal oxide layer is patterned and etched so that there is metal oxide left only on and near the barrier layer 52. After that a capacitor insulator 56 is deposited on the substrate. The capacitor insulator 56 preferably has a high dielectric constant, i.e., it is a high-k material. The high-k material preferably has a dielectric constant greater than about 5. In some embodiments the dielectric constant is greater than about 10 and in other embodiments it is greater than about 20. The high-k layer is optionally annealed to increase the crystallinity and dielectric constant of the layer. Finally, an upper electrode 58 comprising a noble metal oxide is deposited on the high-k material 56, and patterned and etched so that the capacitor can be addressed (electrically accessed). In some arrangements all memory cells for one array are accessed by a common reference electrode, such that patterning within the array may involve only creating openings for cell contacts, such as bit line plugs. In some embodiments only one of the lower 54 or upper electrode 58 comprises a noble metal oxide deposited by ALD. In this case, the other electrode can be formed by conventional means.

Another way of constructing the capacitor is to planarize the substrate surface after the deposition of polysilicon and then form a metal knob of polysilicon. However, a relatively thick layer of metal is needed on the polysilicon plug to increase the effective area of the capacitor. In that case the noble metal oxide deposited by ALD forms the part of the “tooth” that extends above the insulator 36 plane.

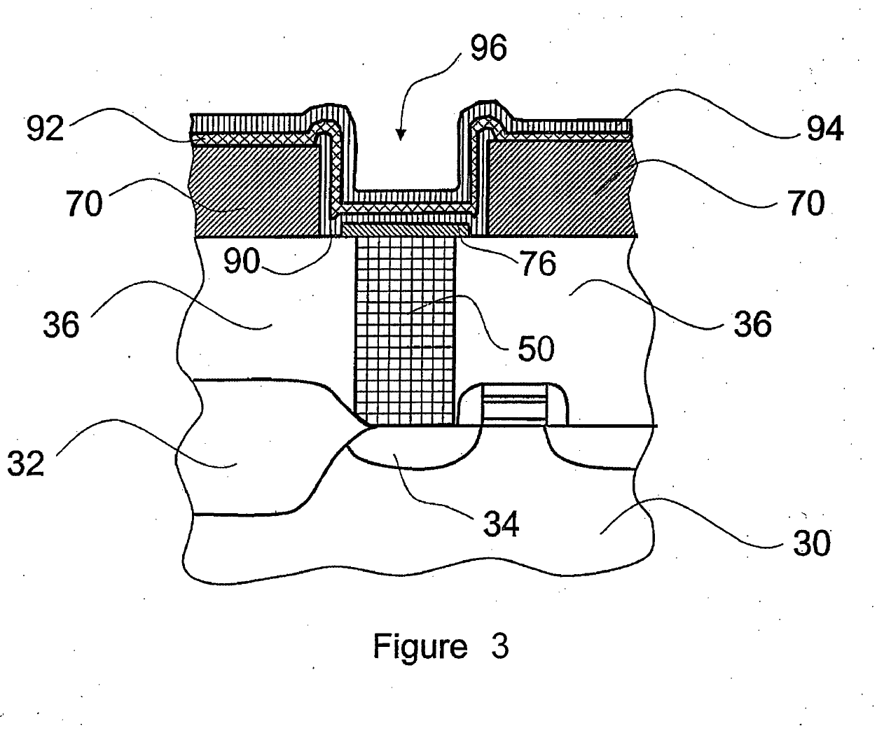

The effective area of the capacitor can also be increased by etching a hollow on a surface and form a capacitor structure on the walls and the bottom of the hollow. As shown in FIG. 3, there is a polysilicon plug 50 extending through the first insulator layer 36. A second insulator layer 70 (e.g., SiO₂) is deposited on the first insulator layer and patterned. The second insulator 70 is etched until a capacitor hollow 96 is formed. A barrier layer 76, e.g., TaₓSi_{y}N_{z}, may deposited on the substrate and patterned so that only the top surface of the polysilicon plug is covered with the barrier 76. However, in some embodiments the barrier layer may be omitted, for example if a noble metal oxide with good barrier properties is utilized as the lower electrode.

A lower metal electrode 90 comprising a conductive noble metal oxide is deposited by ALD on the substrate as described above and patterned and etched so that only the bottom and the walls of the hollow are covered with the lower metal electrode 90. Optionally the second insulation layer 70 can be removed at this stage to expose the outside surfaces of the cup-like shape. High-k dielectric layer 92, e.g. BST, is grown on the substrate by e.g. ALD. An optional annealing step may be used to increase the crystallinity and dielectric constant of the dielectric layer 92. Finally, the upper metal electrode 94, is formed by depositing a conductive noble metal oxide by ALD on the high-k thin film 92 according to the methods discussed above. In some embodiments only one of the upper electrode 94 and lower electrode 90 is formed by depositing a noble metal oxide by ALD and the other electrode is formed conventionally.

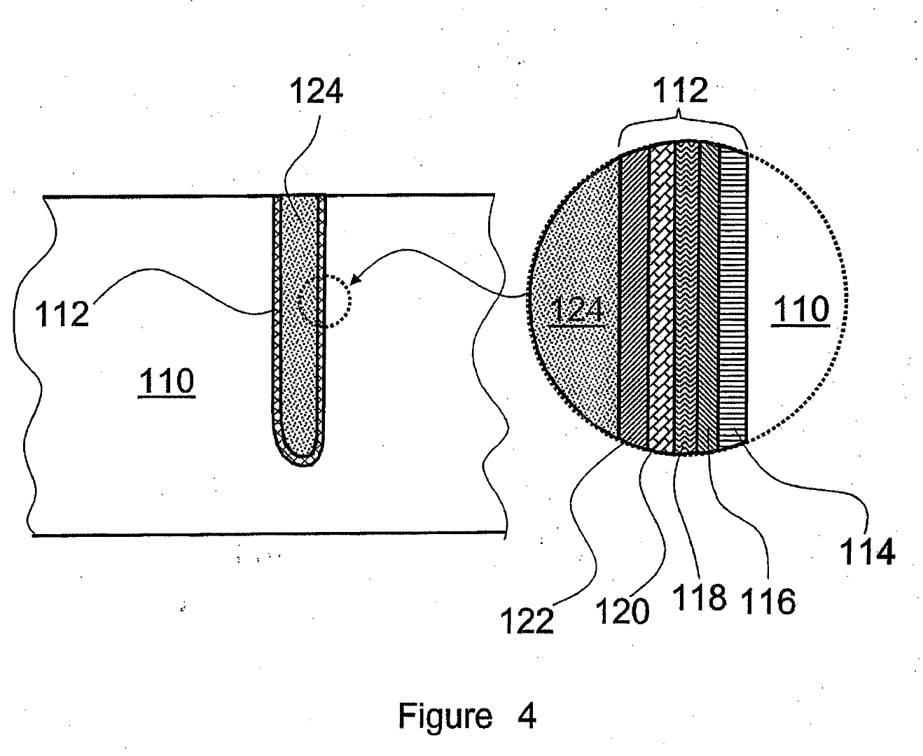

Still another way of increasing the effective area of the DRAM capacitor while keeping the reserved substrate area to a minimum is to place the capacitor structure in a deep pit etched on silicon substrate. The structure is typically referred to as a trench capacitor. FIG. 4 shows a trench capacitor without the addressing lines and semiconducting active components. In a silicon substrate 110 there is a trench with a surface that has been covered with a multi-layer thin film 112. The deposition has started with the formation of a barrier layer 114, e.g., TaₓSi_{y}N_{z}, which is preferably formed between the silicon and a conductive noble metal oxide. However, in some embodiments, for example if the conductive noble metal oxide has good barrier properties, the barrier layer 114 may be omitted.

On the barrier layer 114 a first electrode 116 comprising a noble metal oxide is deposited by ALD as described above. On the first electrode layer 116 a high-k layer 118, e.g., BST, is grown e.g., by ALD. On the high-k layer 118 a second electrode layer 120 comprising a noble metal oxide is grown by ALD as described above. In the case where the trench will be filled with polysilicon 124, it is preferable to protect the second electrode 120 with a barrier thin film 122, e.g., TaₓSi_{y}N_{z}, although in some embodiments, such as where the second electrode layer has good barrier properties, the barrier thin film 122 may be omitted.

In some embodiments, one of the first and second electrodes comprises a noble metal oxide film deposited by ALD and the other is formed conventionally. In other embodiments, the silicon substrate comprises the lower electrode.

In each embodiment, the thickness of the metal oxide electrodes is typically selected from approximately 1 μm up to about 200 nm and even more depending on the application.

The conductive noble metal oxides used as capacitor electrodes in these embodiments is preferably selected from the group consisting of Ru, Re, Os and Ir oxides.

Formation of a Gate Electrode

In some embodiments a gate electrode is formed by ALD of a conductive noble metal oxide.

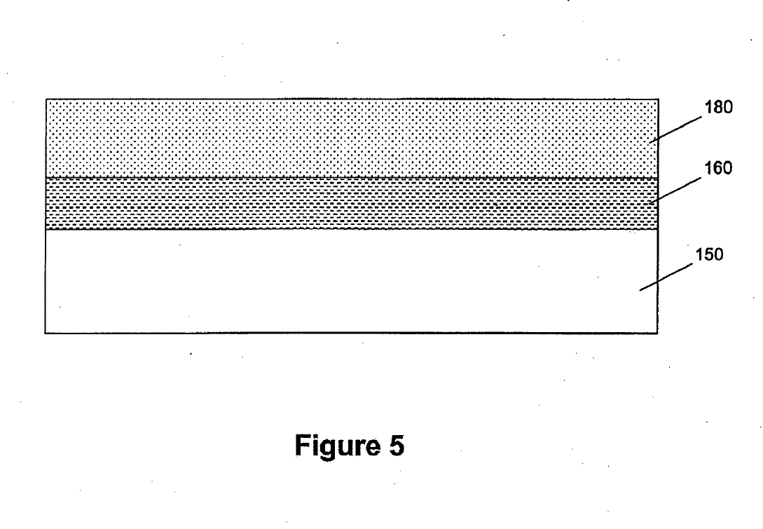

In FIG. 5, a silicon substrate 150 is illustrated comprising a layer of high-k dielectric material 160. The substrate may be treated prior to deposition of the high-k material 160. For example, in some embodiments, a thin interfacial layer (not shown) may be formed prior to deposition of the high-k material 160. In one embodiment a thin chemical oxide or oxynitride is formed on the surface. In other embodiments a thermal oxide is grown on the substrate.

“High-k” generally refers to a dielectric material having a dielectric constant (k) value greater than that of silicon oxide. Preferably, the high-k material has a dielectric constant greater than 5, more preferably greater than about 10. Exemplary high-k materials include, without limitation, HfO₂, ZrO₂, Al₂O₃, TiO₂, Ta₂O₅, Sc₂O₃, lanthanide oxides and mixtures thereof, silicates and materials such as YSZ (yttria-stabilized zirconia), barium strontium titanate (BST), strontium titanate (ST), strontium bismuth tantalate (SBT) and bismuth tantalate (BT). Preferably, the high-k material is also deposited by an ALD process.

A layer of conductive noble metal oxide 180 is deposited over the high-k material 160 by ALD, as described above, to form the structure illustrated in FIG. 5. The noble metal oxide 180 and underlying high-k material 160 are patterned to form a gate electrode.

The noble metal oxide thin film 180 is preferably deposited over the dielectric layer 160 by contacting the substrate with alternating pulses of a noble metal source chemical and an oxygen source chemical as described above. The noble metal source chemical is preferably a betadiketonate compound and the oxygen source chemical is preferably ozone or oxygen plasma products. Unreacted source chemicals and reaction byproducts are removed from the reaction chamber after each source chemical pulse, for example by evacuation and/or purging with an inert gas. The pulsing cycle is repeated until a noble metal oxide layer of the desired thickness has been formed. Preferably, the noble metal oxide layer has a thickness between about 3 nm and about 50 nm.

The conductive noble metal oxides deposited to form the gate electrode in these embodiments are preferably selected from the group consisting of Ru, Re, Os and Ir oxides.

In some embodiments the noble metal oxide 180 forms the gate electrode. In other embodiments (not shown) another conductive material, such as a metal or poly-Si, is deposited over the noble metal oxide 180. The additional conductive material may be deposited by ALD or by another deposition process, such as by CVD or PVD. The deposition may be selective, or may be followed by patterning steps.

Further processing steps, such as spacer deposition and source/drain implantation will be apparent to the skilled artisan.

Formation of a Barrier Layer

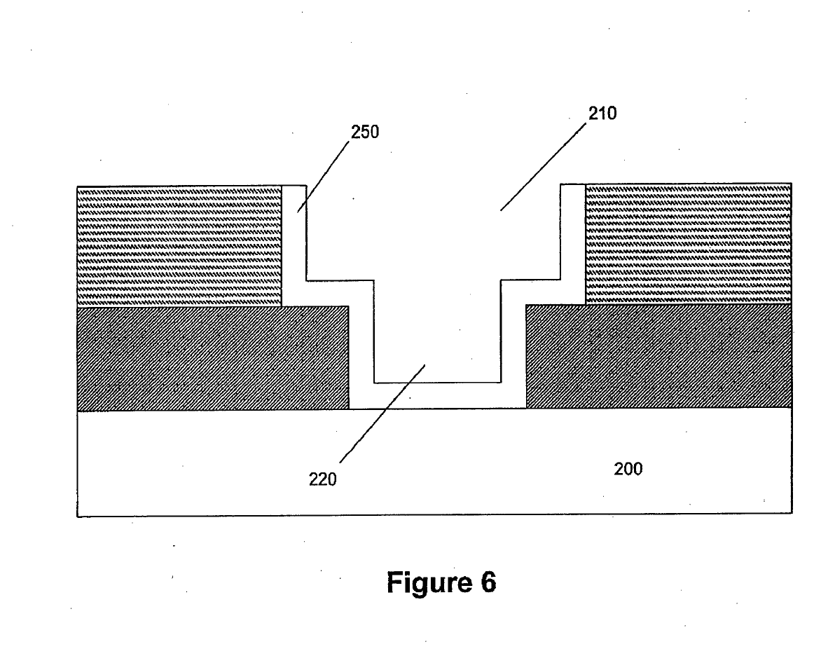

A noble metal oxide thin film can also be deposited by ALD to form a barrier layer for interconnect metallization. The substrate may comprise damascene or dual damascene structures, including high aspect ratio trenches and vias. In one embodiment, a substrate 200 comprising a trench 210 and via 220, as illustrated in FIG. 6, is placed in an ALD reaction chamber. A noble metal oxide thin film barrier layer 250 is then deposited over the trench 210 and via 220 by contacting the substrate 200 with alternating pulses of a noble metal source chemical and an oxygen source. As discussed above, the noble metal source chemical is preferably a betadiketonate compound. The oxygen source is preferably ozone or oxygen plasma products. Unreacted source chemicals and reaction byproducts are removed from the reaction chamber after each source chemical pulse by purging. The pulsing cycle is repeated until a barrier layer 250 of the desired thickness has been formed. Preferably, the barrier layer has a thickness between about 1 nm and about 10 nm.

Formation of a Seed Layer

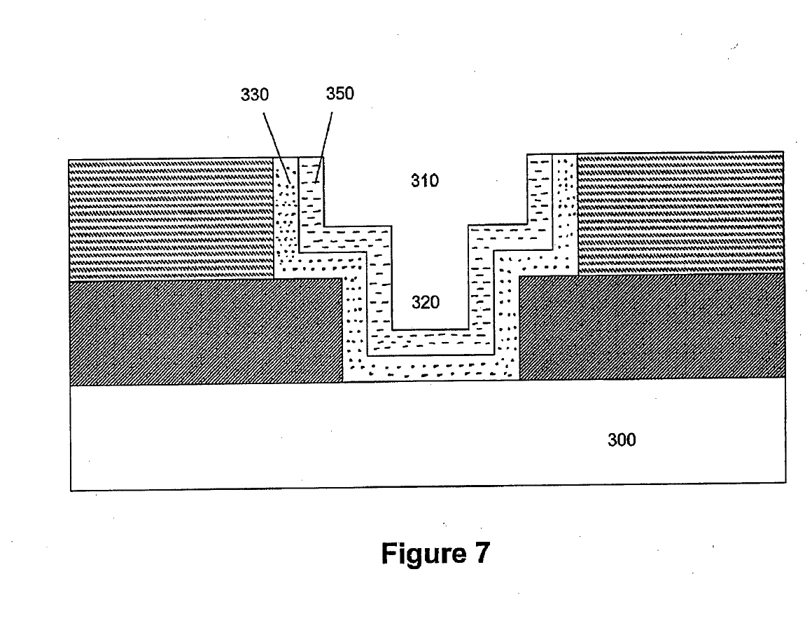

In other embodiments, a noble metal oxide film is deposited by ALD to form a seed layer for interconnect metallization. The seed layer may be deposited, for example, over a damascene or dual damascene structure. In the illustrated embodiment, a substrate 300 comprising a trench 310 and via 320 is placed in the reaction chamber of an ALD reactor (FIG. 7). The structure preferably comprises a diffusion barrier layer 330, which may have been deposited by ALD, for example as described above. The substrate 300 is heated to the deposition temperature, preferably less than about 300° C., more preferably less than about 250° C., and still more preferably less than about 200° C. The substrate 300 is contacted with alternating and sequential pulses of a noble metal precursor and an oxygen source. Pulses of reactants are separated by purging the chamber, preferably by a combination of evacuation with a vacuum pump while flowing an inert gas, such as argon or nitrogen. The pulsing cycle is repeated until a noble metal oxide seed layer 350 of the desired thickness has been formed. In preferred embodiments the thickness of the seed layer is between about 1 nm and about 30 nm or more, depending on the dimensions of the vias and trenches. The noble metal oxide layer is used as a seed layer for metallization, for example copper deposition by electroplating or a CVD process.

The following non-limiting examples will illustrate the invention in more detail.

### EXAMPLE 1

IrO₂ was deposited by ALD on 5×5 cm² soda glass and Si(111) substrates. The substrates were contacted with alternating pulses of Ir(acac)₃ and ozone at a temperature of about 175° C.

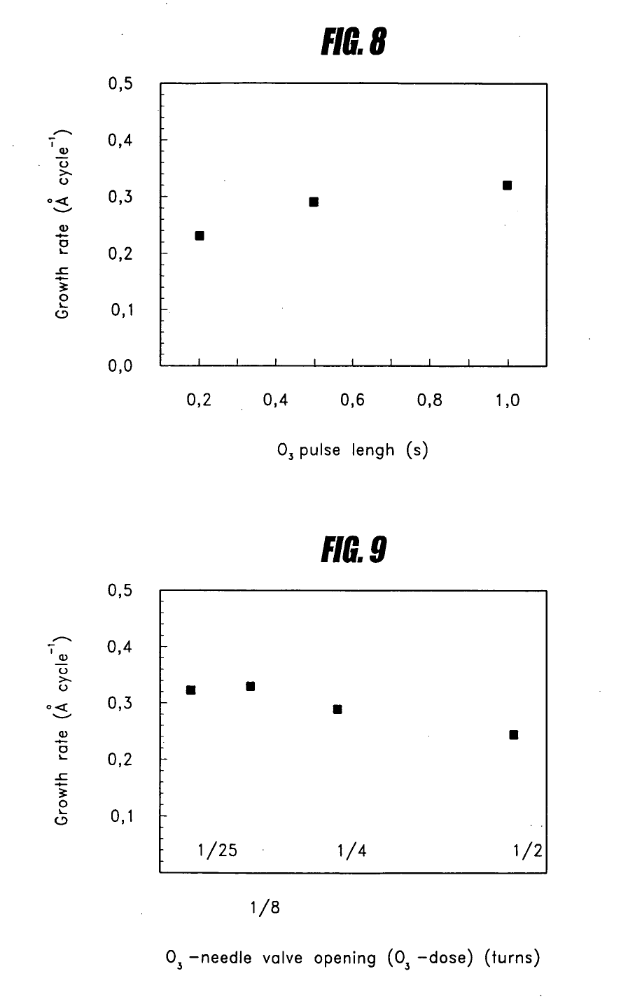

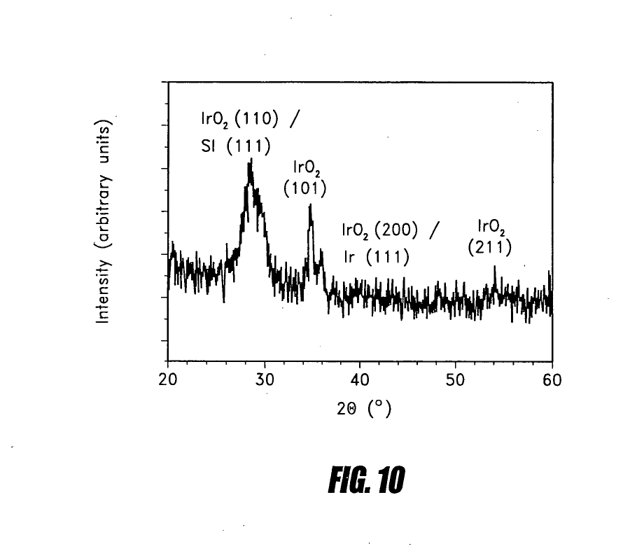

The growth rate of the IrO₂ film saturated at about 0.2 to about 0.3 Å/cycle with increasing ozone pulse time, as illustrated in FIG. 8. Similar results were obtained when the ozone dose was increased by adjusting the ozone needle valve (FIG. 9). XRD measurements revealed that the as-deposited IrO₂ films were amorphous with an identifiable crystalline IrO₂ phase (FIG. 10). Resistivities were about 250 μΩ·cm. The films were dark gray and semitransparent on the soda lime glass substrates and bronze tinted on the silicon substrates.

RhO₂ films were grown on 5×5 cm soda glass and Si(111) substrates by contacting them with alternating pulses of Rh(acac)₃ and ozone at a temperature of about 175° C. to about 200° C. The films were grayish and semitransparent in color and partly reflective.

Although the foregoing invention has been described in terms of certain preferred embodiments, other embodiments will be apparent to those of ordinary skill in the art. Additionally, other combinations, omissions, substitutions and modification will be apparent to the skilled artisan, in view of the disclosure herein. Accordingly, the present invention is not intended to be limited by the recitation of the preferred embodiments, but is instead to be defined by reference to the appended claims.

We claim:

1. An atomic layer deposition (ALD) process for forming a noble metal oxide thin film comprising alternately and sequentially contacting a substrate with a noble metal precursor and an oxygen source, wherein the noble metal precursor comprises a noble metal selected from the group consisting of Ru, Re, Os and Ir and wherein the oxygen source is selected from the group consisting of ozone and oxygen plasma.

2. The process of claim 1, wherein the oxygen source is ozone.

3. The process of claim 1, wherein the process is carried out at a temperature of less than about 300° C.

4. The process of claim 2, wherein the process is carried out at a temperature of less than about 200° C.

5. The process of claim 1, wherein the noble metal precursor comprises a noble metal bound to oxygen, nitrogen or carbon.

6. The process of claim 1, wherein the noble metal precursor is a betadiketonate compound.

7. The process of claim 1, wherein the noble metal oxide thin film is electrically conductive.

8. A process for producing an electrically conductive noble metal oxide on a substrate in a reaction chamber, the process comprising:
exposing the substrate to a vapor phase noble metal precursor such that no more than one monolayer of the precursor is adsorbed on the substrate;
removing excess vapor phase noble metal precursor from the reaction chamber;
exposing the substrate to ozone;
removing excess ozone from the reaction chamber,
wherein the noble metal precursor comprises a noble metal selected from the group consisting of Ru, Re, Os and Ir.

9. The process of claim 8, wherein the noble metal precursor is a betadiketonate compound.

10. The process of claim 8, wherein the process is carried out at a temperature of less than about 300° C.

11. The process of claim 8, wherein the process is carried out at a temperature of less than about 200° C.

12. The process of claim 8, wherein the noble metal oxide forms a capacitor electrode.

13. The process of claim 8, wherein the noble metal oxide is patterned to form a gate electrode.

14. The process of claim 8, wherein the noble metal oxide is a barrier layer in a damascene structure.

15. The process of claim 8, wherein the noble metal oxide is a seed layer in a metal interconnect structure.

16. An atomic layer deposition (ALD) process for forming a conductive noble metal oxide thin film on a substrate in a reaction chamber comprising:
pulsing a vapor phase noble metal precursor into the reaction chamber to form no more than a monolayer of noble metal precursor on the substrate;
removing excess noble metal precursor from the reaction chamber;
pulsing an oxygen source into the reaction chamber to contact the substrate; and
removing excess oxygen source from the reaction chamber,
wherein the noble metal precursor comprises a noble metal selected from the group consisting of Ru, Re, Os and Ir, and wherein the process is carried out at a temperature of less than about 200° C.

17. The process of claim 16, wherein the oxygen source is selected from the group consisting of ozone and oxygen plasma.

18. The process of claim 16, wherein the noble metal precursor is a betadiketonate compound.

19. The process of claim 18, wherein the betadiketonate compound is selected from the group consisting of X(acac)₃ and X(thd)₃, with X being selected from the group consisting of Ru, Re, Os and Ir.

20. The process of claim 18, wherein the beta diketonate compound is X(thd)₃, with X being selected from the group consisting of Ru, Re, Os and Ir.

21. The process of claim 16, wherein the noble metal precursor comprises Ir and the noble metal oxide is IrO₂.

22. The process of claim 16, wherein the noble metal precursor comprises Ru and the noble metal oxide is RuO₂.

23. An atomic layer deposition (ALD) process for forming a noble metal oxide thin film comprising alternately and sequentially contacting a substrate with a noble metal source chemical and an oxygen source, wherein the noble metal source chemical is a betadiketonate compound comprising a noble metal selected from the group consisting of Re, Os and Ir.

24. The process of claim 21, wherein the oxygen source is selected from the group consisting of ozone and oxygen plasma.

25. The process of claim 24, wherein the oxygen source is ozone.

26. The process of claim 21, wherein the process is carried out at a temperature of less than about 200° C.
